(19) United States
(12) Patent Application Publication
(10) Pub. No.: US 2007/0097646 A1
(43) Pub. Date: May 3, 2007

(54) HEAT DISSIPATING APPARATUS FOR COMPUTER ADD-ON CARDS

(76) Inventor: Xue-Wen Peng, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/163,868

(22) Filed: Nov. 2, 2005

(51) Int. Cl. H05K 7/20

(52) U.S. Cl. 361/701

(57) ABSTRACT

A heat dissipating apparatus mounted onto an add-on card (20) includes a base (70), a cover (30) mounted on the base, a plurality of fins (60) received between and thermally connecting the cover and the base, a fan (40) positioned on the base to blow air to the fins, and a heat pipe (50) including an evaporating portion (52) and a condensing portion (54). The evaporating portion and condensing portion are sandwiched between the base and the fins. The cover absorbs heat from the fins and dissipates the heat to ambient air. Thus, the heat dissipating area is increased due to the cover, and the heat dissipating apparatus has a better heat dissipating efficiency.

### FIELD OF THE INVENTION

The present invention relates to a heat dissipating apparatus for computer add-on cards and particularly a heat dissipating apparatus mounted onto a VGA (video graphic array) card for dissipating heat generated by the VGA card, wherein the heat dissipating apparatus has an increased heat dissipating area to thereby enhance heat dissipating efficiency.

### DESCRIPTION OF RELATED ART

Heat sinks serve as cooling devices for heat generating objects such as electronic components or other electronic devices, by absorbing heat generated by such objects and dissipating the absorbed heat into ambient air. Electronic components such as central processing units (CPUs), thermoelectric elements, video graphics array (VGA) cards, and power transistors generate a large amount of heat during operation. When the temperature of an electronic component exceeds a certain level, the electronic component may malfunction or outright fail in the worst case. For this reason, a heat sink is often required to be installed to such a heat generating electronic component to dissipate heat into ambient air.

With the rapid development of science and technology, a variety of electronic components or devices have been highly integrated and miniaturized in recent years. As a consequence, techniques for increasing the surface area of heat dissipating fins as much as possible and shortening the heat conducting pathway in heat sinks have been suggested. By these techniques, the dimensions of heat sinks can be reduced with increased heat dissipating efficiency. However, in a conventional manufacturing process, the heat dissipating fins of a conventional heat sink cannot be made thin enough to increase the heat dissipating efficiency. In addition, the cost for manufacturing extremely thin fins by the conventional methods, i.e., metal extrusion or stamping, is high.

A Heat sink of a heat dissipation device is commonly installed with a fan to increase the heat dissipating efficiency. For example, the fan is installed on top of the heat sink, and blows air over the heat sink, thereby taking heat away from the heat sink. Although cool air is blown to the heat sink by the fan, most of the air cannot fully flow through the fins and is deflected away midways of heat dissipation fins of the heat sink, so that the cooling efficiency of the fan is not high. Moreover, the mounting of the fan on the top of the heat sink makes a total height of the heat dissipation device be too large to be suitable for use in an environment which has a height limitation. In consideration of the increasing need for cooling high-performance and highly integrated electronic components in a small space, there is a need to develop an effective heat dissipating apparatus capable of sufficiently dissipating the heat generated from such electronic components.

### SUMMARY OF INVENTION

Accordingly, what is needed is a heat dissipating apparatus which has an enlarged heat dissipating area and a more efficient means for removing heat therefrom so as to enhance heat dissipating efficiency.

According to a preferred embodiment of the present invention, a heat dissipating apparatus for use with an add-on card, such as a VGA card, comprises a base, a cover spaced from the base, a plurality of fins thermally connecting the cover and the base, a fan positioned on the base to blow air to the fins, and a heat pipe comprising an evaporating portion and a condensing portion. The evaporating portion is sandwiched between the base and the fins. The condensing portion between the fins and the cover. The cover absorbs heat from the fins and the condensing portion of the heat pipe. The fins and the cover dissipate heat to atmosphere immediately. Thus, the heat dissipating apparatus has an increased heat dissipating area and thereby enhancing hat dissipating efficiency.

Other advantages and novel features of the present invention will become more apparent from the following detailed description of preferred embodiment when taken in conjunction with the accompanying drawings, in which:

### BRIEF DESCRIPTION OF DRAWINGS

FIG. 1 is an exploded, isometric view of a heat dissipating apparatus according to a first preferred embodiment of the present invention;

FIG. 2 is an assembled view of FIG. 1;

FIG. 3 is an exploded, isometric view of a heat dissipating apparatus according to a second preferred embodiment of the present invention;

FIG. 4 is an assembled view of FIG. 3; and

FIG. 5 is a side view of FIG. 4.

### DETAILED DESCRIPTION

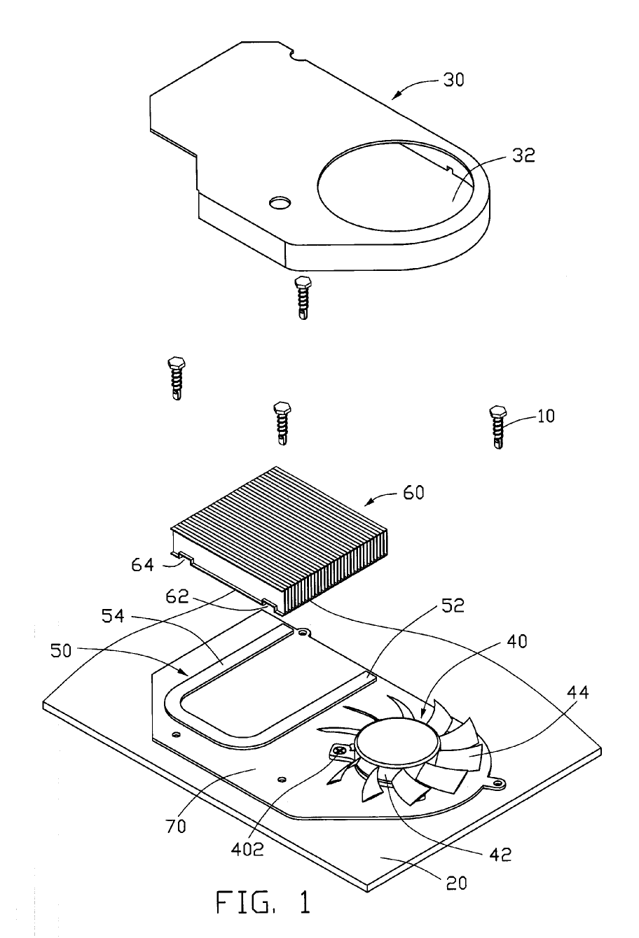

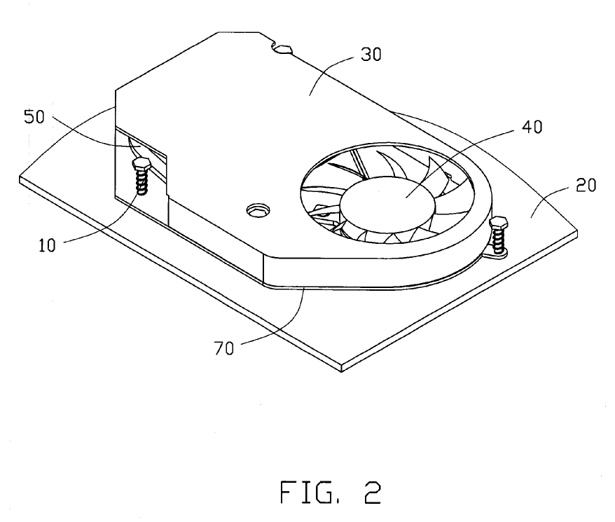

FIGS. 1-2 show a heat dissipating apparatus in accordance with a first preferred embodiment of the present invention. The heat dissipating apparatus mainly comprises a base 70, a plurality fins 60 soldered to the base 70, a heat pipe 50 positioned on the base 70 and extending through the fins 60, a fan 40 located on the base 70, and a cover 30 soldered onto the base 70 and covering the fins 60, the fan 40 and the heat pipe 50. The apparatus is mounted onto an add-on card 20 (such as a VGA card) for dissipating heat generated by a processor (not shown) of the add-on card 20 to achieve effective heat dissipation. For a VGA card, the processor is a GPU (graphic processing unit).

The base 70 is secured to the add-on card 20 by four suitable fasteners 10. Each fin 60 is a single metal piece, and defines first and second parallel rectangular slots 62, 64 at a bottom portion thereof.

The heat pipe 50 has a U-shaped configuration. The heat pipe 50 is flattened and has a rectangular cross-section. The heat pipe 50 is sandwiched between the base 70 and the bottom portion of the fins 60. The heat pipe 50 is filled with working fluid therein and has one end forming an evaporating portion 52 located in the first slot 62 of the fins 60 and another end forming a condensing portion 54 located in the second slot 64 of the fins 60. The first slot 62 is located closer to the fan 40 than the second slot 64. The evaporating portion 52 is parallel to the condensing portion 54 and adjacent to the fan 40. The processor of the add-on card 20 engages a bottom face of the base 70 directly below the evaporating portion 52 of the heat pipe 50. When the evaporating portion 52 absorbs heat from the processor of the add-on card 20, the working fluid in the evaporating portion 52 becomes vapor. The vapor flows to the condensing portion 54 of the heat pipe 50 and is cooled and condensed into liquid. The condensed working fluid flows back to the evaporating portion 52 by capillarity effect on an inner wall of the heat pipe 50 to complete a heat discharging cycle in the heat pipe 50. Thereafter, the circle is repeated.

The fan 40 is a general radial fan (blower) located on the base 70. The fan 40 comprises a hollow hub 42 and a plurality of fan blades 44 extending radially from the hub 42. The fan 40 is mounted to the base 70 by means of screws 402. Airflow generated by the fan 40 flows through channels formed by the fins 60 to dissipate heat absorbed by the fins 60.

The cover 30 has a top wall (not labeled) spaced from the base 70 and defining an opening 32 therein. The opening 32 is aligned with the fan 40. The top wall of the cover 30 is soldered onto the fins 60 so that the fins 60 and the top wall of the cover 30 are thermally connected together. A top portion of the fins 60 is contacted with the cover 30. The cover 30 has a shape similar to that of the base 70. In the illustrated embodiment the cover 30 is made of aluminum but alternatively it could be made of steel, copper or any other suitable material having good thermal conducting characteristics. Heat absorbed by the base 70 goes through the heat pipe 50 and the fins 60 to the cover 30 to achieve an enlarged heat dissipating area. Accordingly, the heat dissipating efficiency of the heat dissipating apparatus is enhanced; the heat is dissipated not only by the fins 60 but also by the cover 30.

Particularly referring to FIG. 2, the fins 60, the heat pipe 50, the fan 40 and the cover 30 are installed on the base 70. One portion of the heat absorbed by the base 70 is distributed over the base 70 along the heat pipe 50, and is transferred to the fins 60 simultaneously and dissipated to ambient air via the fins 60. Meanwhile, airflow generated by the fan 40 flows through the fins 60 to take the heat away from the fins 60 thereby increasing a heat dissipating efficiency of the fins 60. Other portion of the heat absorbed by the base 70 is transferred to the cover 30 via the fins 60 and dissipated by the cover 30 to the ambient air. Heat generated by the processor of the add-on card 20 is thus sufficiently dissipated to the ambient air, and accordingly, the add-on card 20 can operate stably and have an extended life of use. In the present invention, the airflow generated by the fan 40 is drawn from the opening 32 and blown to the fins 60. Due to the restraint of the base 70 and the cover 30, the airflow can only entire flow through the fins 60 to leave the heat dissipating apparatus. Thus, the airflow generated by the fan 40 can be sufficiently used to take the heat of the fins 60 away therefrom, and accordingly, the heat dissipation efficiency of the heat dissipating apparatus is promoted.

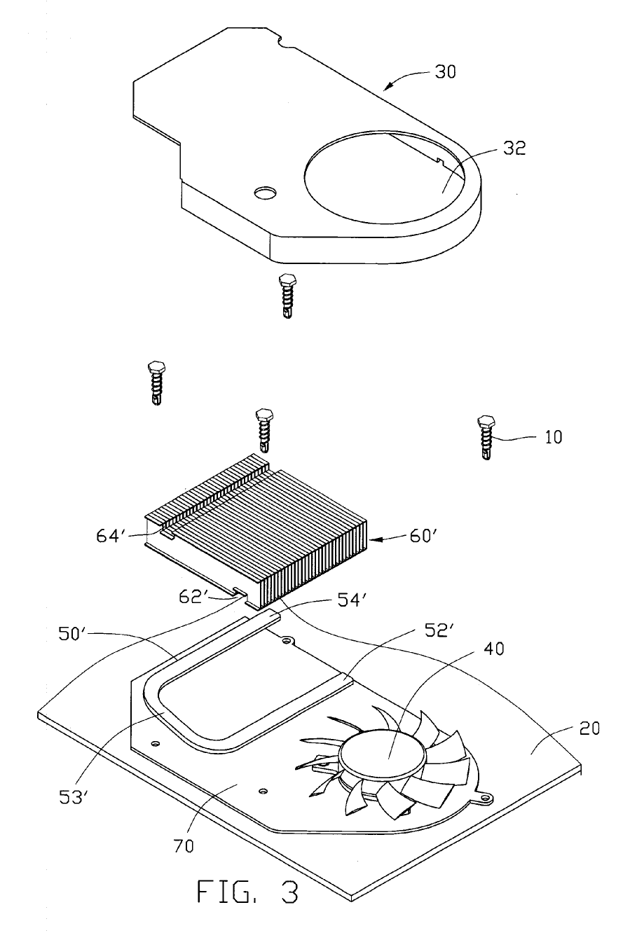

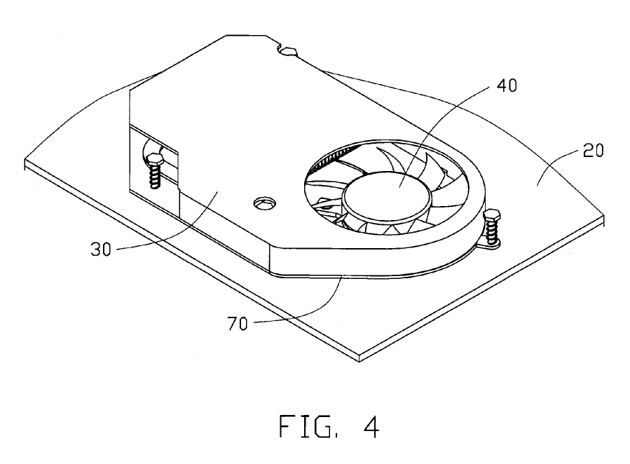

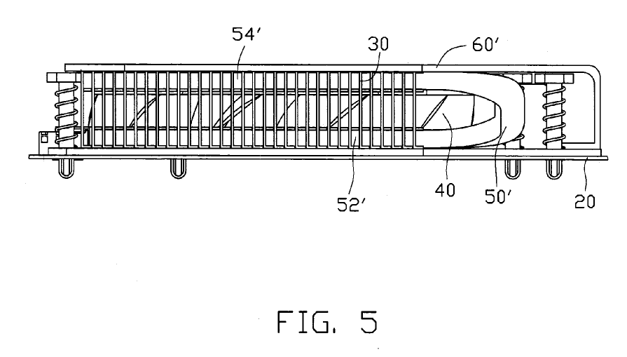

FIGS. 3-5 show a heat dissipating apparatus in accordance with a second preferred embodiment of the present invention. The heat dissipating apparatus of the second preferred embodiment is similar to that of the first preferred embodiment. However, a plurality of fins 60′ replaces the fins 60 of the first embodiment and a heat pipe 50′ replaces the heat pipe 50. The fins 60′ define a first and a second slot 62′, 64′ at a bottom portion and a top portion thereof, respectively. The heat pipe 50′ has a U-shaped configuration, and comprises an evaporating portion 52′ located in the first slot 62′, a condensing portion 54′ located in the second slot 64′ and a connecting portion 53′ connecting the evaporating portion 52′ and the condensing portion 54′. The condensing portion 53′ is thermally connected to the cover 30. In the second preferred embodiment, the evaporating portion 52′ and the condensing portion 54′ of the heat pipe 50 are flattened and have a rectangular cross-section, respectively. The connecting portion 53′ is round and has a circular cross-section.

When the second preferred embodiment of invention is in use, one portion of the heat absorbed by the base 70 is transferred to an upper portion of the fins 60′ via the condensing portion 54′ of the heat pipe 50′ and dissipated to ambient air via the fins 60. Other portion of the heat is transferred to the cover 30 via the fins 60′ and the condensing portion 54′ of the heat pipe 50′, and dissipated by the cover 30 to the ambient air. Thus, the heat dissipating area is increased due to the cover 30. Heat generated by the processor of the add-on card 20 is dissipated efficiently and quickly. Thus the add-on card 20 can operate stably and have an extended life of use.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipating apparatus adapted for dissipating heat generated by an add-on card, comprising:
a base located on the add-on card;
a cover attached on the base and having a top wall spaced from the base;
a plurality of fins thermally connecting the cover and the base;
a fan positioned on the base to blow air to the fins; and
a heat pipe comprising an evaporating portion sandwiched between the base and the fins, and a condensing portion sandwiched between the fins and one of the base and the cover.

2. The heat dissipating apparatus as described in claim 1, wherein the condensing portion of the heat pipe is sandwiched between the base and the fins.

3. The heat dissipating apparatus as described in claim 2, wherein the heat pipe is U-shaped and flattened.

4. The heat dissipating apparatus as described in claim 1, wherein the condensing portion of the heat pipe is sandwiched between the fins and the cover.

5. The heat dissipating apparatus as described in claim 4, wherein the heat pipe further comprise a connecting portion connecting the evaporating portion and the condensing portion, the evaporating portion and the condensing portion are flattened, the connecting portion is round.

6. The heat dissipating apparatus as described in claim 1, wherein the evaporating portion of the heat pipe is located closer to the fan than the condensing portion.

7. The heat dissipating apparatus as described in claim 1, wherein the cover is made of heat conductive material selected from aluminum, copper, the cover dissipates heat absorbed from at least one of the fins and the condensing portion of the heat pipe.

8. The heat dissipating apparatus as described in claim 1, wherein the cover is soldered to the base.

9. A heat dissipating apparatus comprising:
a base;
a plurality of fins located on the base;
a heat pipe located on the base and extending through the fins; and
a cover mounted to the base and absorbing heat from at least one of the fins and the heat pipe, and
dissipating the heat to ambient air.

10. The heat dissipating apparatus as described in claim 9, wherein the heat pipe is U-shaped, the heat pipe comprises an evaporating portion and a condensing portion parallel to the condensing portion.

11. The heat dissipating apparatus as described in claim 10, wherein the evaporating portion of the heat pipe is sandwiched between the base and the fins, the condensing portion thermally connects to the cover and transfer heat from the base to the cover.

12. The heat dissipating apparatus as described in claim 10, wherein the evaporating portion and the condensing portion of the heat pipe are sandwiched between the base and the fins.

13. The heat dissipating apparatus as described in claim 10, further comprises a fan mounted on the base and located near the evaporating portion of the heat pipe.

14. The heat dissipating apparatus as described in claim 11, wherein the cover comprises an opening in alignment with the fan.

15. The heat dissipating apparatus as described in claim 9, wherein the cover is soldered to the fins.

16. A heat dissipating apparatus for an add-on card comprising:
a base for being mounted to the add-on card and thermally connecting with a heat source of the added-one card;
a heat sink mounted on the base;
a fan mounted on the base for driving an airflow through the heat sink;
a cover mounted on the base and thermally connecting with the heat sink; and
a heat pipe having an evaporating portion and a condensing portion, the evaporating portion being located between the fan and the condensing portion.

17. The heat dissipating apparatus of claim 16, wherein the evaporating and condensing portions are located between the heat sink and the base and thermally connected therewith.

18. The heat dissipating apparatus of claim 16, wherein the evaporating portion is located between the heat sink and the base and thermally connected therewith, and the condensing portion is located between the heat sink and the cover and thermally connected therewith.

19. The heat dissipating apparatus of claim 18, wherein the heat pipe has a middle portion interconnecting the evaporating portion and the condensing portion, the middle portion being round while the condensing and evaporating portions are flattened.
